(19) United States
(12) Patent Application Publication
(10) Pub. No.: US 2010/0214372 A1
(43) Pub. Date: Aug. 26, 2010

(54) LIQUID EJECTING HEAD, LIQUID EJECTING APPARATUS, AND ACTUATOR UNIT

(75) Inventor: Motoki TAKABE, Shiojiri-shi (JP)

Correspondence Address: Workman Nydegger;1000 Eagle Gate Tower, 60 East South Temple, Salt Lake City, UT, 84111, US

(73) Assignee: SEIKO EPSON CORPORATION, Tokyo (JP)

(21) Appl. No.: 12/706,377

(22) Filed: Feb. 16, 2010

(30) Foreign Application Priority Data
Feb. 25, 2009 (JP) 2009-043216

(51) Int. Cl. B41J 2/045; H01L 41/00

(52) U.S. Cl. 347/71; 310/364

(57) ABSTRACT

A liquid ejecting head includes a flow channel-forming substrate including a pressure-generating chamber that is in communication with a nozzle opening through which liquid is ejected; and a piezoelectric device that is provided on a surface of the flow channel-forming substrate and is configured to cause change in pressure of the pressure-generating chamber. The piezoelectric device includes a pair of electrodes constituted by a cathode and an anode, and a piezoelectric layer that is sandwiched between the pair of electrodes and is displaceably disposed. A negatively charged region is formed in a portion of the piezoelectric layer, the portion being near the cathode. A positively charged region is formed in a portion of the piezoelectric layer, the portion being near the anode.

### BACKGROUND

1. Technical Field

The present invention relates to a liquid ejecting head, a liquid ejecting apparatus, and an actuator unit.

2. Related Art

A representative example of a liquid ejecting head is, for example, an ink jet recording head. An ink jet recording head is configured to eject ink droplets through a nozzle opening by applying pressure to ink in a pressure-generating chamber with an actuator unit. A portion of the pressure-generating chamber that is in communication with the nozzle opening is constituted by the actuator unit. The actuator unit includes a diaphragm and a piezoelectric device that is provided on the diaphragm and is configured to deform the diaphragm. A piezoelectric device used for such an actuator unit, for example, has a configuration in which a piezoelectric layer composed of a crystallized dielectric material is sandwiched between a lower electrode and an upper electrode (for example, see JP-A-2003-127366, pages 4 to 7 and FIGS. 1 to 4).

In general, enhancement of displacement characteristics of a piezoelectric device has been demanded. For example, to achieve driving of a piezoelectric device at a low voltage, the interfaces between a dielectric material and a pair of electrodes are washed and kept clean (for example, see JP-A-2008-141107, claim 1, FIGS. 1 and 2, and the like).

### SUMMARY

However, at present, a piezoelectric device having even better displacement characteristics, that is, being operable at lower voltage is being demanded. Such a demand for better displacement characteristics is present not only in actuator units mounted to ink jet recording heads configured to eject ink but also in actuator units mounted to liquid ejecting heads configured to eject liquid other than ink and actuator units mounted to apparatuses other than liquid ejecting heads.

An advantage of some aspects of the invention is that an actuator unit having good displacement characteristics, a liquid ejecting head including such an actuator unit, and a liquid ejecting apparatus including such a liquid ejecting head and having good ejection characteristics are provided.

A liquid ejecting head according to an aspect of the invention includes a flow channel-forming substrate including a pressure-generating chamber that is in communication with a nozzle opening through which liquid is ejected; and a piezoelectric device that is provided on a surface of the flow channel-forming substrate and is configured to cause change in pressure of the pressure-generating chamber. The piezoelectric device includes a pair of electrodes constituted by a cathode and an anode, and a piezoelectric layer that is sandwiched between the pair of electrodes and is displaceably disposed. A negatively charged region is formed in a portion of the piezoelectric layer, the portion being near the cathode. A positively charged region is formed in a portion of the piezoelectric layer, the portion being near the anode. In this configuration, a negatively charged region is formed in a portion of the piezoelectric layer, the portion being near the cathode; and a positively charged region is formed in a portion of the piezoelectric layer, the portion being near the anode. As a result, an internal electric field is formed, by the charged regions, in the same direction as that of an electric field formed by applied voltage. Accordingly, the piezoelectric device has higher effective voltage than existing piezoelectric devices by the voltage caused by the internal electric field. Thus, the piezoelectric device has enhanced displacement characteristics, which enhances ejection characteristics of a liquid ejecting head.

Any one of the following configurations is preferably employed. The piezoelectric layer is composed of an oxide, and the negatively charged region contains more oxygen defects than another region of the piezoelectric layer. The piezoelectric layer at least contains Pb, and the negatively charged region contains more divalent Pb ions than another region of the piezoelectric layer. The piezoelectric layer at least contains Pb, and, in the negatively charged region, divalent Pb ions of the piezoelectric layer are replaced with trivalent or higher metal ions. In these configurations, electrons tend to be further accumulated in the negatively charged regions and these regions are further negatively charged.

Any one of the following configurations is preferably employed. The piezoelectric layer is composed of an oxide, and the positively charged region contains more oxygen than another region of the piezoelectric layer. The piezoelectric layer at least contains Pb, and the positively charged region contains less divalent Pb ions than another region of the piezoelectric layer. The piezoelectric layer at least contains Pb, Zr, and Ti, and, in the positively charged region, at least one selected from Zr and Ti of the piezoelectric layer is replaced with trivalent or lower metal ions. The piezoelectric layer at least contains Pb, Zr, and Ti, and the positively charged region contains more Ti than another region of the piezoelectric layer. In these configurations, positive holes tend to be further accumulated in the positively charged regions and these regions are further positively charged.

A liquid ejecting apparatus according to another aspect of the invention includes any one of the above-described liquid ejecting heads. Since such a liquid ejecting apparatus includes any one of the liquid ejecting heads having excellent ejection characteristics, the liquid ejecting apparatus has excellent ejection characteristics.

An actuator unit according to a further aspect of the invention includes a substrate; a pair of electrodes constituted by a cathode and an anode; and a piezoelectric layer that is sandwiched between the pair of electrodes and is displaceably disposed. A negatively charged region is formed in a portion of the piezoelectric layer, the portion being near the cathode. A positively charged region is formed in a portion of the piezoelectric layer, the portion being near the anode. In this configuration, a negatively charged region is formed in a portion of the piezoelectric layer, the portion being near the cathode; and a positively charged region is formed in a portion of the piezoelectric layer, the portion being near the anode. As a result, an internal electric field is formed, by the charged regions, in the same direction as that of an electric field formed by applied voltage. Accordingly, the piezoelectric layer has higher effective voltage than existing piezoelectric layers by the voltage caused by the internal electric field. Thus, the actuator unit has enhanced displacement characteristics.

### BRIEF DESCRIPTION OF THE DRAWINGS

The invention will be described with reference to the accompanying drawings, wherein like numbers reference like elements.

FIG. 1 is an exploded perspective view illustrating the schematic configuration of a recording head according to a first embodiment.

FIG. 2A is a plan view of the recording head according to the first embodiment. FIG. 2B is a sectional view of the recording head according to the first embodiment.

FIG. 3A is a schematic view illustrating the distribution of electric fields in an existing recording head. FIG. 3B is a schematic view illustrating the distribution of electric fields in the recording head according to the first embodiment.

FIGS. 4A to 4C are sectional views illustrating a method for producing the recording head according to the first embodiment.

FIGS. 5A and 5B are sectional views illustrating a method for producing the recording head according to the first embodiment.

FIGS. 6A and 6B are sectional views illustrating a method for producing the recording head according to the first embodiment.

FIGS. 7A to 7C are sectional views illustrating a method for producing the recording head according to the first embodiment.

FIGS. 8A and 8B are sectional views illustrating a method for producing the recording head according to the first embodiment.

FIGS. 9A and 9B are sectional views illustrating a method for producing the recording head according to the first embodiment.

FIG. 10 is a schematic view illustrating the configuration of a recording apparatus according to an embodiment.

### DESCRIPTION OF EXEMPLARY EMBODIMENTS

Hereinafter, the invention will be described in detail with reference to embodiments.

### First Embodiment

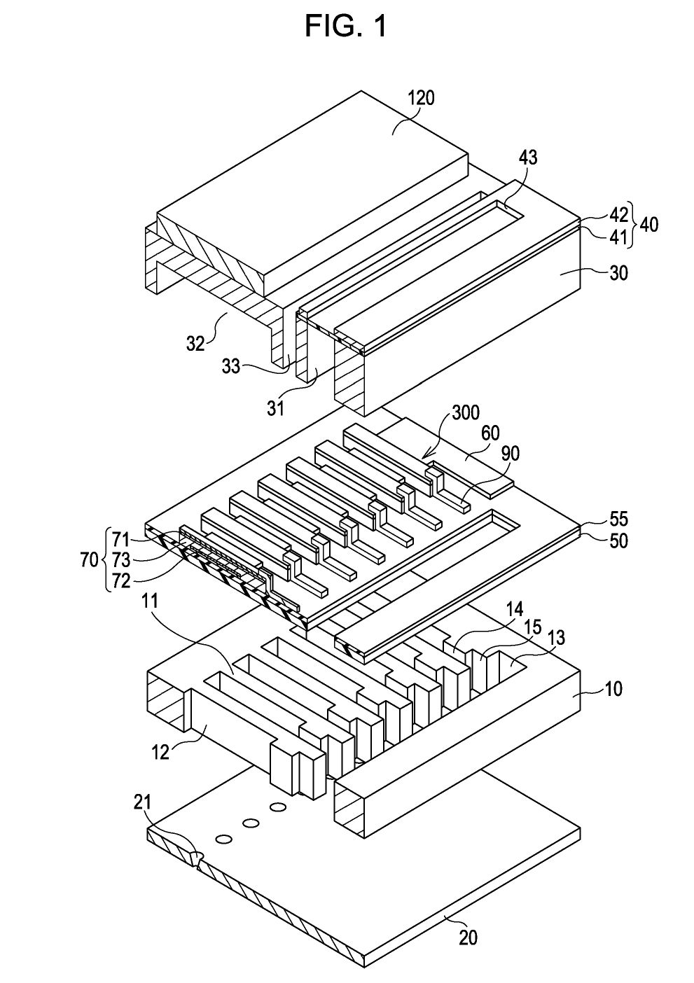

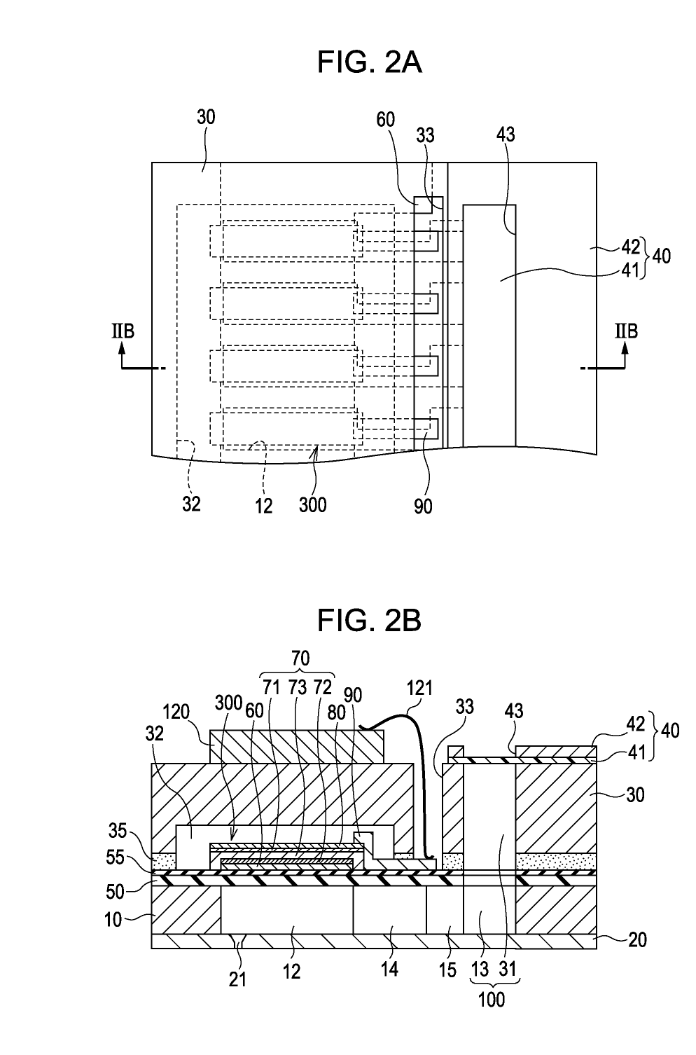

FIG. 1 is an exploded perspective view illustrating the schematic configuration of an ink jet recording head serving as an example of a liquid ejecting head according to a first embodiment of the invention. FIG. 2A is a plan view of the ink jet recording head in FIG. 1. FIG. 2B is a sectional view taken along section line IIB-IIB of FIG. 2A.

In the first embodiment, a flow channel-forming substrate 10 is a silicon single crystal substrate having a (110) plane orientation. Referring to FIGS. 1 and 2B, an elastic film 50 composed of silicon dioxide is formed on one surface of the flow channel-forming substrate 10 in advance by thermal oxidation.

The flow channel-forming substrate 10 includes a plurality of pressure-generating chambers 12 defined by dividing walls 11, the pressure-generating chambers 12 being formed by anisotropically etching the other surface of the flow channel-forming substrate 10. The pressure-generating chambers 12 are arranged parallel to each other in the width direction (transverse direction) of the flow channel-forming substrate 10. The dividing walls 11 also define ink supply paths 14 and communication paths 15 that are formed at end portions of the pressure-generating chambers 12 of the flow channel-forming substrate 10 in the longitudinal direction of the pressure-generating chambers 12. A communication portion 13 is provided at ends of the communication paths 15. The communication portion 13 is a part of a reservoir 100 that serves as a common ink chamber (liquid chamber) for all the pressure-generating chambers 12. In summary, the flow channel-forming substrate 10 includes a liquid flow channel including the pressure-generating chambers 12, the communication portion 13, the ink supply paths 14, and the communication paths 15.

A nozzle plate 20 is secured to the opening surface of the flow channel-forming substrate 10 with an adhesive, a thermal welding film, or the like. The nozzle plate 20 includes nozzle openings 21 extending therethrough and being in communication with regions near end portions of the pressure-generating chambers 12, the end portions being opposite the ink supply paths 14.

An insulation film 55 is formed on the elastic film 50, which is provided on a surface of the flow channel-forming substrate 10, the surface being opposite the opening surface. A lower electrode film 60 having a thickness of, for example, about 0.2 μm; a piezoelectric layer 70 having a thickness of, for example, about 1.1 μm; and an upper electrode film 80 having a thickness of, for example, about 0.05 μm are further stacked on the insulation film 55 by a process described below to thereby constitute piezoelectric devices 300. Herein, each piezoelectric device 300 is a part including the lower electrode film 60, the piezoelectric layer 70, and the upper electrode film 80. In general, one of the electrodes of each piezoelectric device 300 is formed as a common electrode and the other electrode and the piezoelectric layer 70 are provided for each pressure-generating chamber 12 by patterning. In the first embodiment, the lower electrode film 60 is formed as the common electrode of the piezoelectric devices 300 and the upper electrode film 80 is provided as individual electrodes for the piezoelectric devices 300. Alternatively, depending on the arrangement of a driving circuit or wiring, the upper electrode film 80 may be formed as the common electrode of the piezoelectric devices 300 and the lower electrode film 60 may be provided as individual electrodes for the piezoelectric devices 300. Herein, the piezoelectric devices 300 and a diaphragm that undergoes displacement by the driving of the piezoelectric devices 300 are collectively referred to as an actuator unit. Although the elastic film 50, the insulation film 55, and the lower electrode film 60 function as a diaphragm in the first embodiment, the configuration of such a diaphragm is not restricted thereto. For example, the following configuration may also be employed: the elastic film 50 and the insulation film 55 are not formed and the lower electrode film 60 only functions as a diaphragm. Alternatively, the piezoelectric devices 300 may also be configured to substantially function as a diaphragm.

The piezoelectric layer 70 is formed on the lower electrode film 60 and is a crystalline film having a perovskite structure and composed of a piezoelectric oxide material having a polarized structure. The piezoelectric layer 70 is preferably formed of a ferroelectric material such as lead zirconate titanate (PZT), a material obtained by adding a metal oxide such as niobium oxide, nickel oxide, or magnesium oxide to such a ferroelectric material, or the like. Specifically, the following materials may be used: lead titanate (PbTiO₃), lead zirconate titanate (Pb(Zr, Ti)O₃), lead zirconate (PbZrO₃), lead lanthanum titanate ((Pb, La)TiO₃), lead lanthanum zirconate titanate ((Pb, La)(Zr, Ti)O₃), lead zirconium titanate magnesium niobate (Pb(Zr, Ti)(Mg, Nb)O₃), and the like. In the first embodiment, the piezoelectric layer 70 is composed of lead zirconate titanate (Pb(Zr, Ti)O₃).

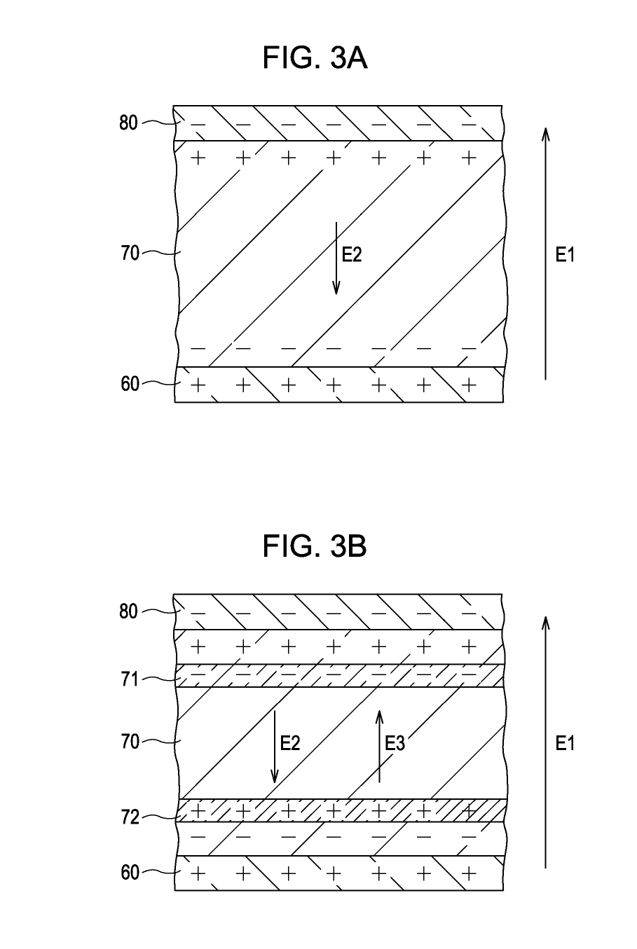

A negatively charged layer 71, which is negatively charged, is formed in the piezoelectric layer 70 and at the interface between the piezoelectric layer 70 and the upper electrode film 80. A positively charged layer 72, which is positively charged, is formed in the piezoelectric layer 70 and at the interface between the piezoelectric layer 70 and the lower electrode film 60. Thus, the piezoelectric layer 70 includes the positively charged layer 72, a piezoelectric layer body 73, and the negatively charged layer 71 that are stacked in this order. The presence of the positively charged layer 72 and the negatively charged layer 71 in the piezoelectric layer 70 results in the formation of an internal electric field between the positively charged layer 72 and the negatively charged layer 71. In the first embodiment, since the positively charged layer 72 and the negatively charged layer 71 are arranged such that the internal electric field is formed in the same direction as an electric field formed between the lower electrode film 60 and the upper electrode film 80 by the application of a voltage, the effective voltage of the piezoelectric device 300 can be increased. Accordingly, the displacement characteristics of the piezoelectric devices serving as an actuator unit can be enhanced. Hereinafter, this respect will be described in detail with reference to FIGS. 3A and 3B. FIGS. 3A and 3B are schematic views for illustrating electric fields in piezoelectric devices. FIG. 3A illustrates an existing piezoelectric device. FIG. 3B illustrates a piezoelectric device according to the first embodiment. In the first embodiment, the positively charged layer 72 and the negatively charged layer 71 are formed at the interfaces between the piezoelectric layer 70 and the electrode films. However, for purposes of illustration, the positively charged layer 72 and the negatively charged layer 71 in FIG. 3B are not shown at the interfaces between the piezoelectric layer 70 and the electrode films.

Referring to FIG. 3A, in existing piezoelectric devices, the positively charged layer 72 and the negatively charged layer 71 are not formed in the piezoelectric layer 70. In this case, the application of a voltage with the lower electrode film 60 serving as an anode and the upper electrode film 80 serving as a cathode causes accumulation of charge in these electrode films. The accumulated charge forms an electric field E1 from the lower electrode film 60 to the upper electrode film 80 in the piezoelectric device. An internal electric field E2 is also formed in a direction opposite to the electric field E1 in the piezoelectric layer 70 as a result of the application of the voltage. Accordingly, an effective electric field E applied to the piezoelectric device satisfies the following equation: E=E1−E2. Thus, a voltage smaller than the applied voltage is finally applied to the piezoelectric device.

In contrast, referring to FIG. 3B, in the piezoelectric device according to the first embodiment, the positively charged layer 72 and the negatively charged layer 71 are formed in the piezoelectric layer 70. A charged-layer internal electric field E3 from the positively charged layer 72 to the negatively charged layer 71 is formed between the positively charged layer 72 and the negatively charged layer 71 by the charged layers. In this case, the application of a voltage with the lower electrode film 60 serving as an anode and the upper electrode film 80 serving as a cathode causes accumulation of charge in these electrode films. The accumulated charge forms an electric field E1 from the lower electrode film 60 to the upper electrode film 80 in the piezoelectric device 300. An internal electric field E2 is also formed in a direction opposite to the electric field E1 in the piezoelectric layer 70 as a result of the application of the voltage. As described above, the charged-layer internal electric field E3 is further formed in the same direction as the electric field E1. Accordingly, an effective electric field E applied to the piezoelectric device 300 satisfies the following equation: E=E1−E2+E3.

Thus, in the first embodiment, an effective voltage larger than those in existing piezoelectric devices by the strength of the charged-layer internal electric field E3 can be obtained. Accordingly, in the piezoelectric device 300 according to the first embodiment, the piezoelectric layer 70 can undergo larger displacement than in existing piezoelectric devices under the application of the same voltage. Thus, the piezoelectric device 300 has improved displacement characteristics. As a result, an ink jet recording head including the piezoelectric device 300 according to the first embodiment has good liquid ejecting characteristics.

Hereinafter, the negatively charged layer 71 and the positively charged layer 72 will be described in detail. The negatively charged layer 71 is in the state of being charged with negative electric charge, that is, in the state of including excessive electrons due to the presence of a donor impurity in a large amount. The positively charged layer 72 is in the state of being charged with positive electric charge, that is, in the state of including excessive positive holes due to the presence of an acceptor impurity in a large amount. Accordingly, an electric field is formed by the presence of the negative charge and the positive charge between the negatively charged layer 71 and the positively charged layer 72. The term “impurity” in the first embodiment not only refers to an impurity that is actually present but also may refer to a defect or the like.

The negatively charged layer 71 is, for example, a layer formed so as to contain less oxygen than the piezoelectric layer body 73, that is, in an oxygen defect state. In the first embodiment, the piezoelectric layer body 73 is composed of lead zirconate titanate (Pb(Zr, Ti)O₃) and the composition of the lead zirconate titanate in the piezoelectric layer body 73 satisfies Pb:(Zr+Ti):O=(1.08 to 1.24):1:(3 to 3.5). Pb is present as divalent lead ions in the piezoelectric layer body 73. In contrast, the negatively charged layer 71 is formed, for example, so as to contain the divalent lead ions in an excessively large amount compared with the piezoelectric layer body 73, or trivalent metal ions such as trivalent iron ions or trivalent aluminum ions as a result of replacement of the divalent lead ions with the trivalent metal ions. In the above-described cases, oxygen defects, excessive lead ions, and metal ions that have replaced lead ions function as donor impurities. Thus, the negatively charged layer 71 containing such a donor impurity can hold excessive electrons and hence is negatively charged. Formation of the negatively charged layer 71 will be described below.

The positively charged layer 72 is, for example, a layer formed so as to have excessive oxygen compared with the piezoelectric layer body 73. Pb is present as divalent lead ions in the piezoelectric layer body 73. In contrast, the positively charged layer 72 is formed, for example, so as to contain less divalent lead ions than the piezoelectric layer body 73, that is, in a lead defect state; trivalent or lower metal ions such as trivalent iron ions or trivalent aluminum ions as a result of replacement of at least one selected from Ti and Zr with the metal ions; or excessive Ti as a result of addition of Ti. In the above-described cases, excessive oxygen, lead defects, trivalent or lower metal ions that have replaced at least one selected from Ti and Zr, and excessive Ti function as acceptor impurities. Thus, the positively charged layer 72 containing such an acceptor impurity can hold excessive positive holes and hence is positively charged. Formation of the positively charged layer 72 will be described below.

Referring back to FIGS. 1, 2A, and 2B, lead electrodes 90 are formed on the upper electrode films 80 serving as individual electrodes of the piezoelectric devices 300. Each lead electrode 90 extends from a region near an end, on the ink supply path 14 side, of each upper electrode film 80 to the insulation film 55. The lead electrode 90 is composed of, for example, gold (Au).

A protection substrate 30 including a reservoir portion 31 constituting at least a portion of the reservoir 100 is bonded with an adhesive 35 onto the flow channel-forming substrate 10 on which the piezoelectric devices 300 are formed, that is, above the lower electrode film 60, the elastic film 50, and the lead electrodes 90. In the first embodiment, the reservoir portion 31 is formed so as to extend through the protection substrate 30 in the thickness direction and in the width direction of the pressure-generating chambers 12. As described above, the reservoir portion 31 is in communication with the communication portion 13 of the flow channel-forming substrate 10, so that the reservoir portion 31 and the communication portion 13 together constitute the reservoir 100 serving as a common ink chamber for the pressure-generating chambers 12.

The protection substrate 30 includes, in a region facing the piezoelectric devices 300, a piezoelectric-device containing portion 32 having a space in which motion of the piezoelectric devices 300 is not hampered. The piezoelectric-device containing portion 32 will suffice as long as it has a space in which motion of the piezoelectric devices 300 is not hampered and the space may be sealed or not.

The protection substrate 30 includes a through hole 33 extending therethrough in the thickness direction. A portion of each lead electrode 90 extending from each piezoelectric device 300, the portion including an end of the lead electrode 90, is exposed in the through hole 33.

A driving circuit 120 for driving the piezoelectric devices 300 arranged side by side is fixed on the protection substrate 30. The driving circuit 120 is constituted by, for example, a circuit board or a semiconductor integrated circuit (IC). The driving circuit 120 and the lead electrodes 90 are electrically connected to each other with connection wiring 121 constituted by conductive wires such as bonding wires.

A compliance substrate 40 including a seal film 41 and a fixing plate 42 is bonded onto the protection substrate 30. The seal film 41 is composed of a material having low stiffness and having flexibility. A face of the reservoir portion 31 is sealed with the seal film 41. The fixing plate 42 is composed of a hard material such as a metal (for example, stainless steel (SUS)). The fixing plate 42 has, in a region facing the reservoir 100, an opening portion 43 that is entirely hollowed in the thickness direction of the fixing plate 42. Thus, a face of the reservoir 100 is sealed only with the seal film 41 having flexibility.

Such an ink jet recording head according to the first embodiment is configured to work as follows. Ink is introduced from an ink introduction port connected to an external ink supply unit (not shown) so that the internal space extending from the reservoir 100 to the nozzle openings 21 is filled with the ink. After that, a voltage is applied, in accordance with recording signals from the driving circuit 120, between the lower electrode film 60 and the upper electrode films 80 associated with the pressure-generating chambers 12 with the lower electrode film 60 serving as an anode and the upper electrode films 80 serving as cathodes. As a result, the elastic film 50, the lower electrode film 60, and the piezoelectric layers 70 are deformed to thereby increase the internal pressure of the pressure-generating chambers 12, which results in ejection of ink droplets through the nozzle openings 21. In the first embodiment, since the positively charged layer 72 and the negatively charged layer 71 are formed in each piezoelectric layer 70, the piezoelectric layer 70 undergoes larger displacement than existing piezoelectric layers under the application of the same voltage.

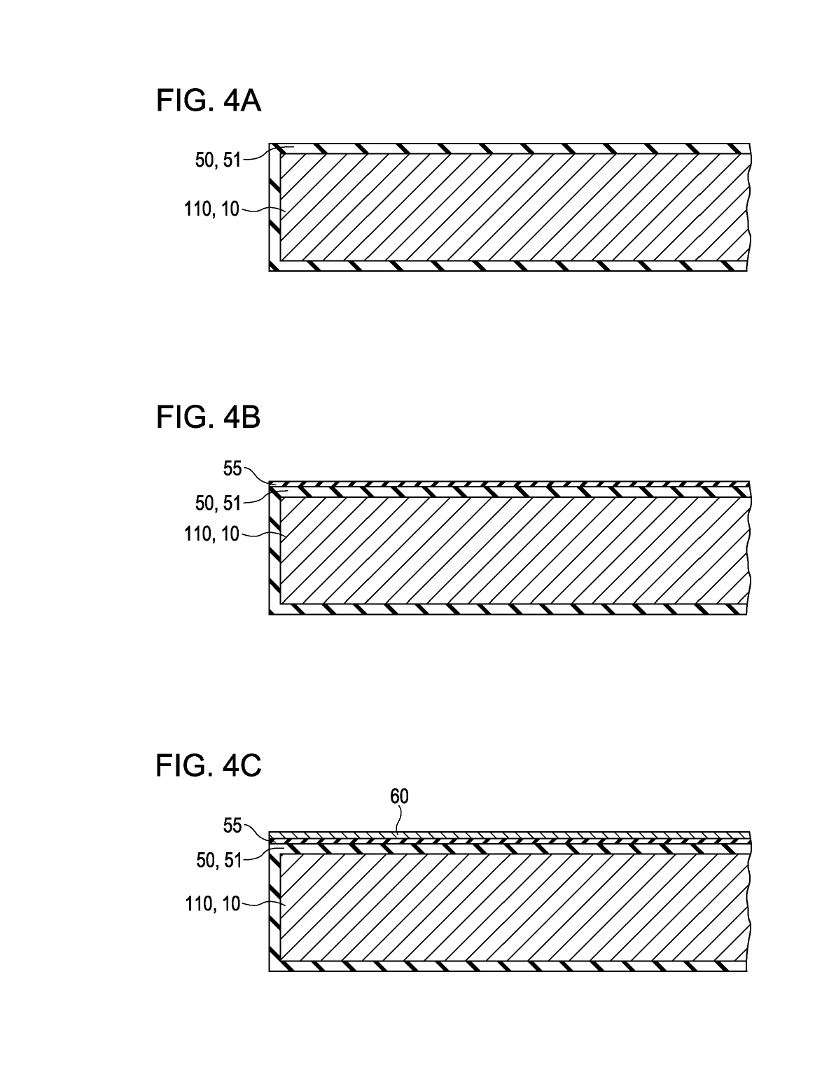

Hereinafter, a method for producing such an ink jet recording head will be described with reference to FIGS. 4A to 9B. FIGS. 4A to 9B are sectional views in the longitudinal direction of pressure-generating chambers, the sectional views illustrating a method for producing an ink jet recording head that serves as an example of a liquid ejecting head according to the first embodiment of the invention.

Referring to FIG. 4A, a wafer 110 (silicon wafer) for forming a flow channel-forming substrate is thermally oxidized to thereby form a silicon dioxide film 51 that is composed of silicon dioxide (SiO₂) and includes the elastic film 50 in the surface. Hereinafter, the wafer 110 for forming a flow channel-forming substrate will be simply referred to as the wafer 110.

Referring to FIG. 4B, the insulation film 55 composed of zirconium oxide is subsequently formed on the elastic film 50 (silicon dioxide film 51).

Referring to FIG. 4C, the lower electrode film 60 composed of, for example, platinum and iridium are subsequently formed over the entire surface of the insulation film 55.

The piezoelectric layer 70 composed of lead zirconate titanate (PZT) is subsequently formed. In the first embodiment, the piezoelectric layer 70 is formed by the following sol-gel process. A sol in which an organometallic compound is dissolved and dispersed into a solvent is coated and dried to provide a gel. The gel is then fired at high temperature to form the piezoelectric layer 70 composed of a metal oxide. However, a method for forming the piezoelectric layer 70 is not restricted to such a sol-gel process. For example, the piezoelectric layer 70 may be formed by MOD (metal-organic decomposition) process or the like.

In the first embodiment, to form the piezoelectric layer 70, the positively charged layer 72 is firstly formed. As described above, the positively charged layer 72 contains an acceptor impurity and a method for forming the positively charged layer 72 is determined in accordance with the type of the acceptor impurity to be contained. In the following description, a case where excessive Ti is used as an acceptor impurity will be described and other cases in which other acceptor impurities are used will be described after that.

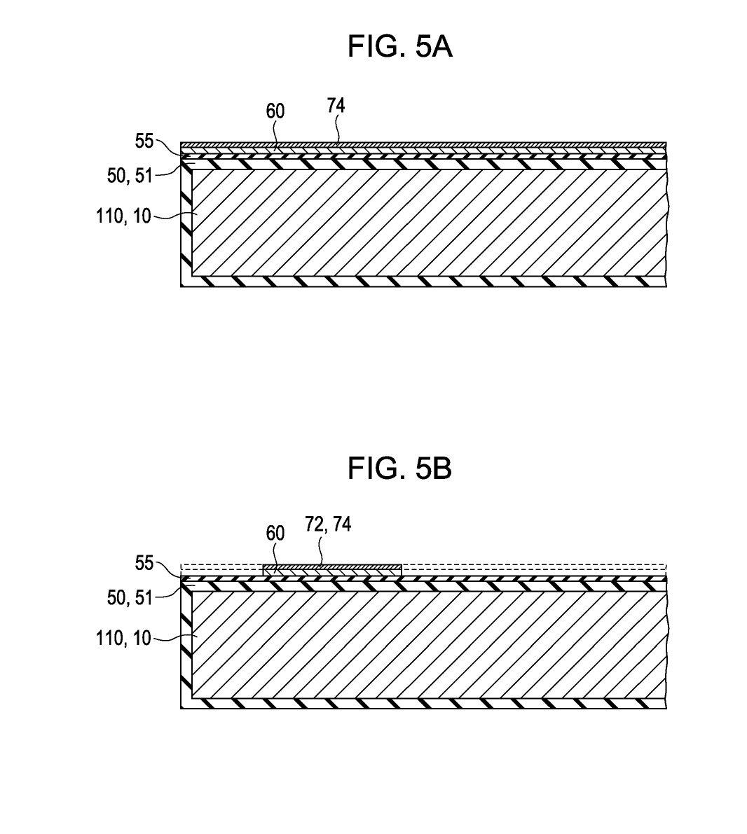

Referring to FIG. 5A, a positively charged layer film 74 is formed on the lower electrode film 60 with a solution for forming a positively charged film, the solution having a higher Ti content than a solution for forming a piezoelectric precursor described below. Specifically, a sol (solution) containing an organometallic compound (including a Ti organic compound) is coated onto the lower electrode film 60 on the wafer 110. The coated solution is subsequently dried for a period of time by being heated to a certain temperature.

After the drying, the resultant film is degreased by being heated and held at a certain temperature for a period of time. In the first embodiment, the term “degrease” refers to removal of organic components contained in a film by turning the organic components into, for example, NO₂, CO₂, and H₂O.

The resultant film is then crystallized by being heated and held again at a certain temperature for a period of time. Thus, the positively charged layer film 74 containing excessive Ti as an acceptor impurity is formed. Referring to FIG. 5B, when the positively charged layer film 74 is formed on the lower electrode film 60, the lower electrode film 60 and the positively charged layer film 74 are simultaneously patterned by dry etching such as ion milling to thereby form the positively charged layer 72.

After the patterning of the lower electrode film 60 and the positively charged layer film 74, the piezoelectric layer body 73 is formed. The piezoelectric layer body 73 can be formed in a manner similar to that in which the positively charged layer 72 is formed. A piezoelectric precursor film that is a PZT precursor film is formed on the wafer 110 including the positively charged layer 72. Specifically, a sol (solution) containing an organometallic compound is coated onto the wafer 110 and the resultant piezoelectric precursor film is subsequently dried for a period of time by being heated to a certain temperature. For example, in the first embodiment, the piezoelectric precursor film can be dried by being held at 170° C. to 180° C. for 8 to 30 minutes.

The dried piezoelectric precursor film is subsequently degreased by being heated and held at a certain temperature for a period of time. For example, in the first embodiment, the piezoelectric precursor film is degreased by being heated and held at about 300° C. to 400° C. for about 10 to 30 minutes.

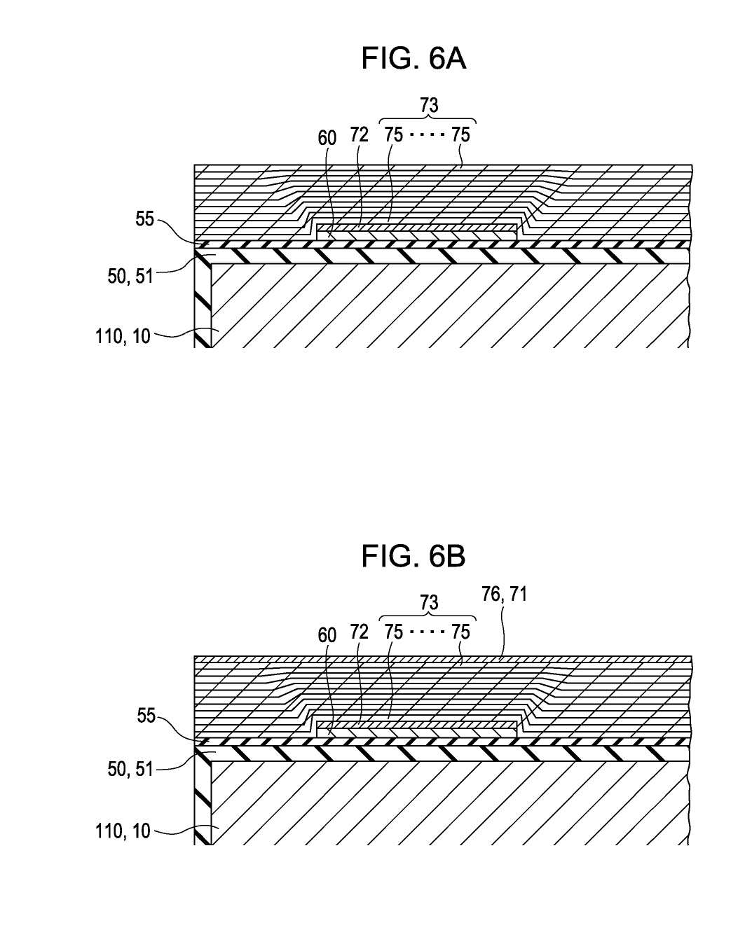

The resultant piezoelectric precursor film is subsequently crystallized by being heated and held at a certain temperature for a period of time in an oxygen atmosphere (partial pressure of oxygen: 15% to 100%) to thereby form a piezoelectric film 75. Referring to FIG. 6A, a plurality of the piezoelectric films 75 are formed by repeating the process of forming a piezoelectric film.

Referring to FIG. 6B, a negatively charged layer film 76 to serve as the negatively charged layer 71 is subsequently formed on the piezoelectric layer body 73. As described above, the negatively charged layer 71 contains a donor impurity and a method for forming the negatively charged layer film 76 is determined in accordance with the type of the donor impurity to be contained. In the following description, a case where oxygen defects are used as a donor impurity will be described and other cases in which other donor impurities are used will be described after that.

In the first embodiment, when the uppermost piezoelectric film is formed, the piezoelectric precursor film is fired in a reducing atmosphere such as a nitrogen (N₂) atmosphere or a hydrogen (H₂) atmosphere. As a result, the negatively charged layer film 76 containing more oxygen defects serving as a donor impurity than the other region (piezoelectric layer body 73) can be formed as the uppermost piezoelectric layer. As described above, when the piezoelectric film 75 is formed by firing, firing of the piezoelectric precursor film in an oxygen atmosphere (partial pressure of oxygen: 15% to 100%) results in formation of the piezoelectric film 75 composed of normal PZT. In contrast, firing of the piezoelectric precursor film in a reducing atmosphere containing no oxygen (for example, 100% nitrogen atmosphere) results in formation of the negatively charged layer film 76 composed of PZT having oxygen defects. The negatively charged layer film 76 is not completely free from oxygen and contains oxygen in an amount because oxygen is supplied from the underlying piezoelectric film 75 upon the firing of the piezoelectric precursor film.

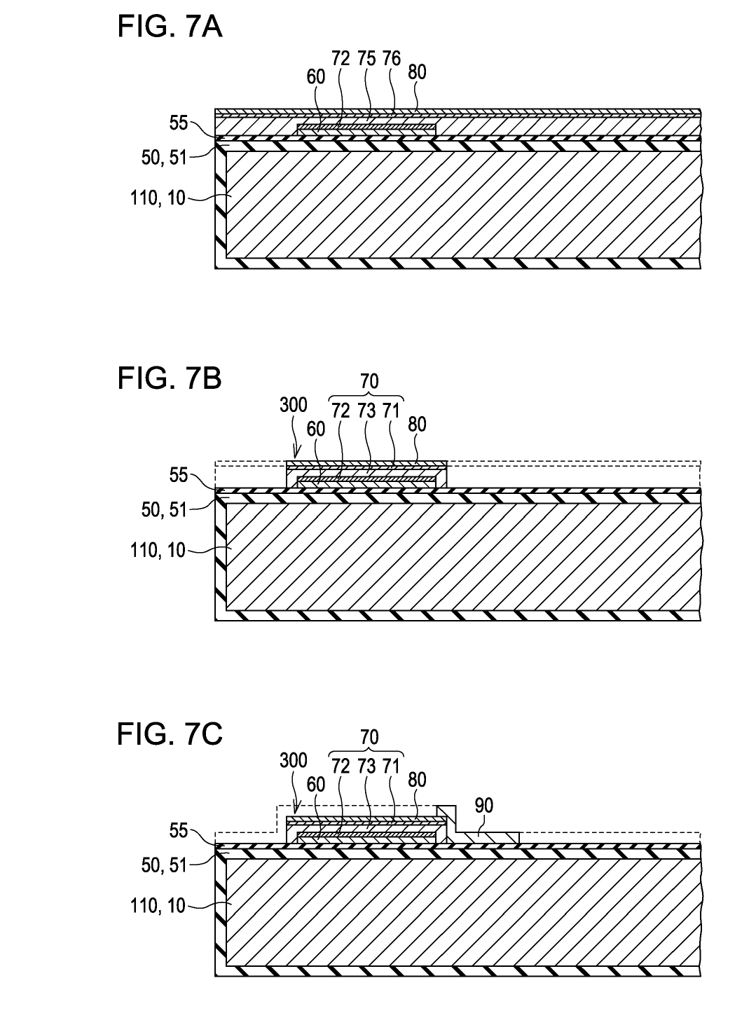

Referring to FIG. 7A, the upper electrode film 80 is subsequently formed over the entire surface of the piezoelectric layer 70 (negatively charged layer film 76).

Referring to FIG. 7B, the piezoelectric film 75, the negatively charged layer film 76, and the upper electrode film 80 are patterned into regions associated with the pressure-generating chambers 12 to thereby form the piezoelectric devices 300 including the piezoelectric layers 70. The patterning is conducted by, for example, dry etching such as reactive ion etching or ion milling.

The lead electrodes 90 are subsequently formed. Specifically, referring to FIG. 7C, the lead electrode 90 is formed over the entire surface of the wafer 110 and subsequently patterned into the lead electrodes 90 associated with the piezoelectric devices 300 through a mask pattern (not shown) composed of, for example, resist.

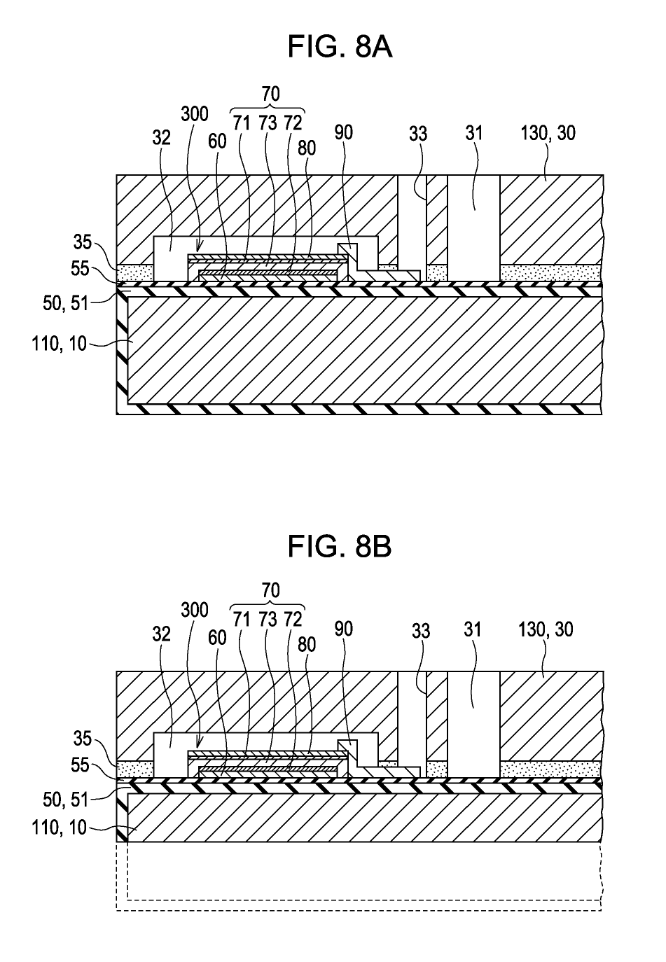

Referring to FIG. 8A, a wafer (silicon wafer) 130 for forming the protection substrates, to serve as a plurality of the protection substrates 30 is bonded with the adhesive 35 to a surface of the wafer 110, the surface being equipped with the piezoelectric devices 300. Hereinafter, the wafer 130 for forming the protection substrates will be simply referred to as the wafer 130.

Referring to FIG. 8B, the wafer 110 is subsequently thinned to a predetermined thickness.

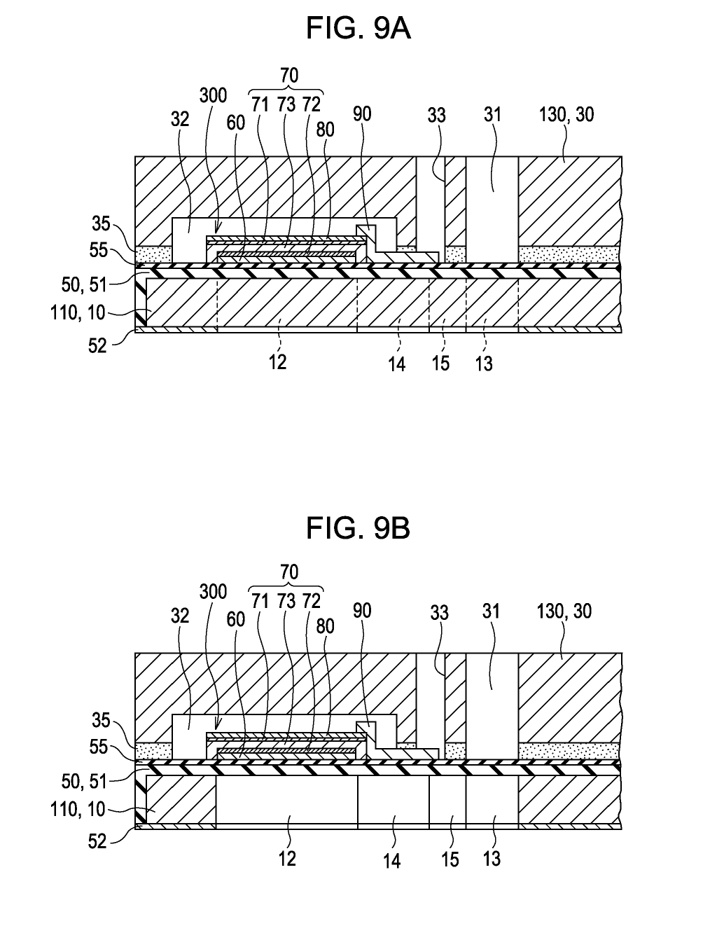

Referring to FIG. 9A, a mask film 52 is subsequently formed on the wafer 110 and the mask film 52 is patterned so as to have a predetermined pattern. Referring to FIG. 9B, the wafer 110 is subjected to anisotropic etching (wet etching) with an alkaline solution such as KOH through the mask film 52 to thereby form the pressure-generating chambers 12, the communication portion 13, the ink supply paths 14, the communication paths 15, and the like associated with the piezoelectric devices 300.

After that, unnecessary portions in the circumferential portions of the wafer 110 and the wafer 130 are removed by cutting, for example, dicing. The nozzle plate 20 including the nozzle openings 21 extending therethrough is subsequently bonded to a surface of the wafer 110, the surface being opposite the wafer 130. The compliance substrate 40 is bonded to the wafer 130. The wafer 110 and the like are then divided into the flow channel-forming substrates 10 having the size of a chip in FIG. 1. Thus, ink jet recording heads according to the first embodiment are produced.

The thus-produced ink jet recording head according to the first embodiment was subjected to measurement of displacement under the application of a driving voltage (pulse voltage, pulse width: 200 μsec, applied voltage: 25 V). The measured displacement was 520 nm. An existing ink jet recording head was also subjected to measurement of displacement under the application of the same driving voltage. The measured displacement was 490 nm. Accordingly, it has been demonstrated that the displacement has been increased by 30 nm in the ink jet recording head according to the first embodiment under the application of the same driving voltage.

Hereinafter, methods for forming the positively charged layer films 74 containing other acceptor impurities will be described.

A case where the positively charged layer film 74 containing excessive oxygen as an acceptor impurity is formed will be described. In this case, for example, the positively charged layer film 74 is formed at a degreasing temperature (about 420° C. to 500° C.) higher than that in the formation of the piezoelectric layer body 73. In general, when the bond between oxygen and a metal in the piezoelectric precursor is weak, the bond tends to be broken and the oxygen is released upon firing. Such degreasing at high temperature strengthens the bond between oxygen and a metal and suppresses release of the oxygen to thereby keep excessive oxygen in the positively charged layer film 74. Alternatively, a coating solution for forming the positively charged layer film 74 may be prepared with polyethylene glycol having a high molecular weight (for example, a molecular weight of 10,000 g/mol or more) serving as a solvent. When a polyethylene glycol having a high molecular weight is used, decomposition of the polyethylene glycol in processes takes time and the components of the polyethylene glycol tend to remain in the positively charged layer film 74. Thus, oxygen in the polyethylene glycol is present in a large amount in the positively charged layer film 74. As a result, the positively charged layer film 74 can be formed so as to contain a large amount of oxygen.

To form the positively charged layer film 74 containing lead defects as an acceptor impurity, for example, a solution having a lower lead content than a solution for forming the piezoelectric precursor film is prepared and the positively charged layer film 74 is formed with the prepared solution.

To form the positively charged layer film 74 containing trivalent or lower metal ions as an acceptor impurity as a result of replacement of at least one selected from Ti and Zr with the metal ions, for example, a solution for forming the piezoelectric precursor film is prepared so as to contain, as an additive, desired metal ions used to replace at least one selected from Ti and Zr (or an organometallic compound containing the metal ions). Since the trivalent or lower metal ions are contained as an additive in the solution, in the positively charged layer film 74 formed with the solution, at least one selected from Ti and Zr is replaced with the trivalent or lower metal ions.

To form the positively charged layer film 74 containing excessive Ti as an acceptor impurity, as described above, a solution may be prepared so as to contain excessive Ti. Alternatively, for example, a thin Ti film is formed by sputtering or the like and a piezoelectric precursor film is formed on the Ti film. In this case, a portion of the piezoelectric precursor film near the Ti film functions as the positively charged layer film 74 containing excessive Ti. Alternatively, for example, after a Ti film is formed, the positively charged layer film 74 may be formed with a solution containing excessive Ti as described above.

Hereinafter, methods for forming the negatively charged layer film 76 containing other donor impurities will be described.

To form the negatively charged layer film 76 containing excessive lead ions as a donor impurity, for example, a solution having a higher lead content than a solution for forming the piezoelectric precursor film is prepared and the negatively charged layer film 76 is formed with the prepared solution. In this case, to suppress diffusion of excessive lead, the upper electrode film 80 is formed with a metal that is less likely to allow passing of lead through the metal such as iridium, osmium, or ruthenium and the upper electrode film 80 is subjected to a heat treatment upon the formation of the upper electrode film 80.

To form the negatively charged layer film 76 containing trivalent or higher metal ions as a donor impurity as a result of replacement of Pb with the metal ions, for example, a solution for forming the piezoelectric precursor film is prepared so as to contain, as an additive, desired metal ions used to replace Pb. Since the trivalent or higher metal ions are contained as an additive in the solution, in the negatively charged layer film 76 formed with the solution, lead ions are replaced with the trivalent or higher metal ions.

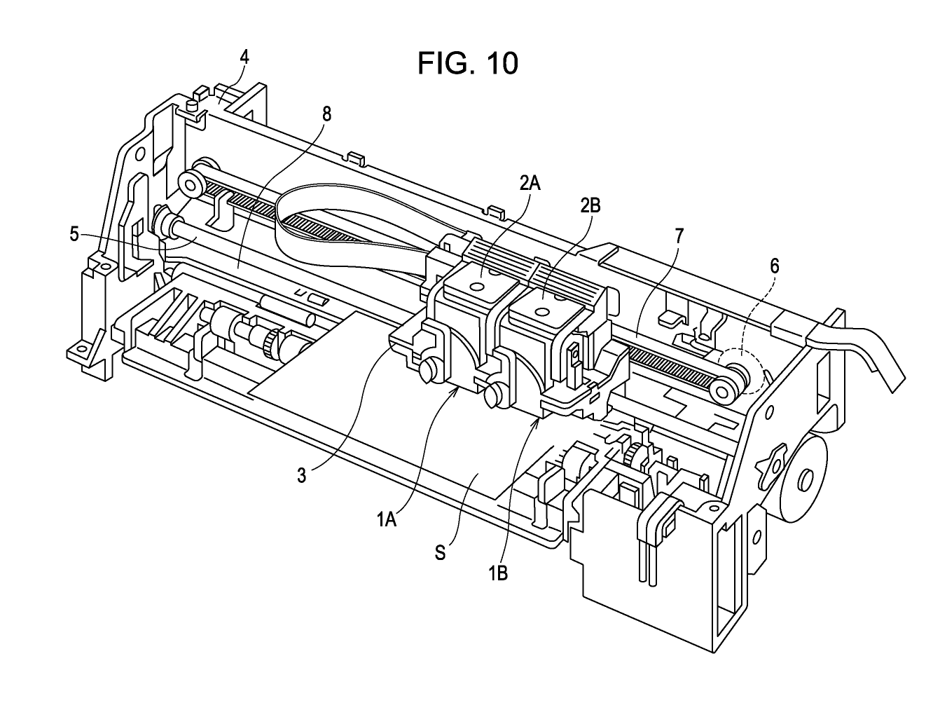

An ink jet recording apparatus including such an ink jet recording head will be described with reference to FIG. 10. FIG. 10 is a schematic view illustrating an example of such an ink jet recording apparatus. The above-described ink jet recording head is incorporated into the ink jet recording apparatus so as to constitute a portion of a recording head unit including ink flow channels in communication with an ink cartridge and the like. Cartridges 2A and 2B constituting an ink supply unit are respectively detachably mounted to recording head units 1A and 1B including the ink jet recording heads. A carriage 3 on which the recording head units 1A and 1B are mounted is in turn mounted to a carriage shaft 5 secured to an apparatus body 4 such that the carriage 3 is freely movable along the carriage shaft 5. The recording head units 1A and 1B are respectively configured to eject, for example, a black ink composition and a color ink composition.

A driving force of a driving motor 6 is transferred via a plurality of gears (not shown) and a timing belt 7 to thereby cause the carriage 3 on which the recording head units 1A and 1B are mounted to move along the carriage shaft 5. A platen 8 is provided along the carriage shaft 5 in the apparatus body 4. A recording sheet S, which is a recording media such as paper supplied by a paper feed roller (not shown), is transported on the platen 8. Since an ink jet recording apparatus according to the first embodiment includes the above-described ink jet recording head having good ink ejecting characteristics, the ink jet recording apparatus has excellent printing characteristics.

### Other Embodiments

Although an embodiment according to the invention has been described so far, a basic configuration of the invention is not restricted to the first embodiment. For example, although the negatively charged layer 71 is provided on the upper electrode film 80 side in the first embodiment, the invention is not restricted to this configuration and the negatively charged layer 71 will suffice as long as the negatively charged layer 71 is provided on the cathode side. For example, when the lower electrode film 60 is used as a cathode and the upper electrode film 80 is used as an anode, the negatively charged layer 71 may be provided on the lower electrode film 60 side of the piezoelectric layer 70 and the positively charged layer 72 may be provided on the upper electrode film 80 side of the piezoelectric layer 70. In such a case where the order of stacking is opposite to that in the first embodiment, for example, an upper electrode film, a positively charged layer, a piezoelectric layer body, a negatively charged layer, and a lower electrode film are stacked in this order on a substrate to provide a piezoelectric device, and the piezoelectric device is transferred onto the flow channel-forming substrate 10.

Although the positively charged layer 72 is formed so as to contain excessive Ti and the negatively charged layer 71 is formed so as to contain oxygen defects in the first embodiment, the combination of the type of the positively charged layer 72 and the type of the negatively charged layer 71 is not restricted thereto. Although the positively charged layer 72 and the negatively charged layer 71 are respectively formed at the interfaces between the piezoelectric layer 70 and the upper electrode film 80 and the lower electrode film 60 in the first embodiment, the positively charged layer 72 and the negatively charged layer 71 are not necessarily formed at the interfaces and will suffice as long as the positively charged layer 72 and the negatively charged layer 71 are formed in portions near the upper electrode film 80 and the lower electrode film 60. Although the positively charged layer 72 and the negatively charged layer 71 are each constituted by a monolayer in the first embodiment, they may be constituted by two or more layers.

Although a piezoelectric precursor film is coated, dried, degreased, and subsequently fired to thereby form the piezoelectric film 75 in the first embodiment, the invention is not restricted to the first embodiment. For example, the piezoelectric film 75 may be formed by repeating the step of coating, drying, and degreasing a piezoelectric precursor film several times, for example, twice, and subsequently firing the piezoelectric precursor film.

Although a silicon single crystal substrate having a (110) crystal plane orientation is used as an example of the flow channel-forming substrate 10 in the first embodiment, the invention is not particularly restricted to the first embodiment. For example, a silicon single crystal substrate having a (100) crystal plane orientation may be used. Alternatively, an SOI substrate or a substrate composed of glass or the like may also be used.

Although an actuator unit including the piezoelectric devices 300 in which the lower electrode film 60, the piezoelectric layer 70, and the upper electrode film 80 are stacked in this order on the substrate (flow channel-forming substrate 10) is described as an example in the first embodiment, the invention is not particularly restricted to the first embodiment. For example, the invention may also be applied to an actuator unit including a piezoelectric device of an axial oscillation type that is obtained by alternately stacking a piezoelectric material and an electrode-forming material and is configured to expand and contract in the axial direction of the piezoelectric device.

An ink jet recording head is described as an example of a liquid ejecting head in the first embodiment. However, the invention is generally directed to various liquid ejecting heads and can also be applied to liquid ejecting heads configured to eject liquids other than ink. Examples of such liquid ejecting heads include various recording heads used for image recording apparatuses such as printers; colorant ejecting heads used for producing color filters of liquid crystal displays or the like; electrode material ejecting heads used for forming electrodes of organic EL displays, FEDs (field emission displays), or the like; and organic biomaterial ejecting heads used for producing biochips or the like.

The invention is applied not only to actuator units mounted to liquid ejecting heads such as ink jet recording heads and methods for producing such actuator units but also to actuator units mounted to other apparatuses, methods for producing such actuator units, and methods for driving such actuator units.

An ink jet recording apparatus in which the recording head units 1A and 1B are mounted on the carriage 3 and moved in the main scanning direction was described above as an example. However, the invention is not particularly restricted to such an ink jet recording apparatus. For example, the invention may also be applied to a line recording apparatus in which an ink jet recording head (or a head unit) is fixed and printing is conducted by moving a recording sheet S such as a paper sheet in the subscanning direction.

What is claimed is:

1. A liquid ejecting head comprising:
a flow channel-forming substrate including a pressure-generating chamber that is in communication with a nozzle opening through which liquid is ejected; and
a piezoelectric device that is provided on a surface of the flow channel-forming substrate and is configured to cause change in pressure of the pressure-generating chamber,
wherein, the piezoelectric device includes a pair of electrodes constituted by a cathode and an anode, and a piezoelectric layer that is sandwiched between the pair of electrodes and is displaceably disposed,
a negatively charged region is formed in a portion of the piezoelectric layer, the portion being near the cathode, and
a positively charged region is formed in a portion of the piezoelectric layer, the portion being near the anode.

2. The liquid ejecting head according to claim 1, wherein the piezoelectric layer is composed of an oxide, and the negatively charged region contains more oxygen defects than another region of the piezoelectric layer.

3. The liquid ejecting head according to claim 1, wherein the piezoelectric layer at least contains Pb, and the negatively charged region contains more divalent Pb ions than another region of the piezoelectric layer.

4. The liquid ejecting head according to claim 1, wherein the piezoelectric layer at least contains Pb, and, in the negatively charged region, divalent Pb ions of the piezoelectric layer are replaced with trivalent or higher metal ions.

5. The liquid ejecting head according to claim 1, wherein the piezoelectric layer is composed of an oxide, and the positively charged region contains more oxygen than another region of the piezoelectric layer.

6. The liquid ejecting head according to claim 1, wherein the piezoelectric layer at least contains Pb, and the positively charged region contains less divalent Pb ions than another region of the piezoelectric layer.

7. The liquid ejecting head according to claim 1, wherein the piezoelectric layer at least contains Pb, Zr, and Ti, and, in the positively charged region, at least one selected from Zr and Ti of the piezoelectric layer is replaced with trivalent or lower metal ions.

8. The liquid ejecting head according to claim 1, wherein the piezoelectric layer at least contains Pb, Zr, and Ti, and the positively charged region contains more Ti than another region of the piezoelectric layer.

9. A liquid ejecting apparatus comprising the liquid ejecting head according to claim 1.

10. An actuator unit comprising:
a substrate;
a pair of electrodes constituted by a cathode and an anode; and
a piezoelectric layer that is sandwiched between the pair of electrodes and is displaceably disposed,
wherein, a negatively charged region is formed in a portion of the piezoelectric layer, the portion being near the cathode, and
a positively charged region is formed in a portion of the piezoelectric layer, the portion being near the anode.
